(19) United States
(12) Patent Application Publication
(10) Pub. No.: US 2008/0159018 A1
(43) Pub. Date: Jul. 3, 2008

(54) SEMICONDUCTOR MEMORY DEVICE HAVING INTERNAL VOLTAGE GENERATION CIRCUITS

(75) Inventor: Tatsuya Matano, Tokyo (JP)

Correspondence Address: Young & Thompson, 745 S. 23rd Street., Second Floor, Arlington, VA, 22202, US

(73) Assignee: ELPIDA MEMORY, INC., Tokyo (JP)

(21) Appl. No.: 11/959,600

(22) Filed: Dec. 19, 2007

(30) Foreign Application Priority Data
Dec. 22, 2006 (JP) 2006-345353

(51) Int. Cl. G11C 7/00; G11C 8/00

(52) U.S. Cl. 365/189.09; 365/230.03

(57) ABSTRACT

A semiconductor memory device according to the present invention comprising: n memory banks, where n is an integer more than 1; a first internal voltage generation circuit allocated to corresponding m memory banks, where m is an integer equal to or smaller than the n; and a second internal voltage generation circuit allocated to corresponding p memory banks, where p is an integer equal to or smaller than the n, wherein the first internal voltage generation circuit supplies an internal voltage when one of corresponding banks is in an active state, and the second internal voltage generation circuit supplies the internal voltage in a period in which one of corresponding banks is in the active state and in which a predetermined operation is performed.

### TECHNICAL FIELD

The present invention relates to a semiconductor memory device, and, more particularly to a semiconductor memory device in which a plurality of memory banks are arranged in a distributed fashion.

### BACKGROUND OF THE INVENTION

A semiconductor memory device typified by a DRAM (Dynamic Random Access Memory) is often configured so that a memory cell array is divided into a plurality of memory banks so as to enable parallel operations inside. Commands can be individually issued from outside of the semiconductor memory device to the respective memory banks. The memory banks have different active periods accordingly.

Each of the memory banks differs in power consumption between an active state and a standby state. Normally, therefore, both an internal voltage generation circuit for standby state that is constantly activated and an internal voltage generation circuit for active state that is activated only while the corresponding memory bank is in the active state are employed (see Japanese Patent Application Laid-Open No. 2006-127727).

Generally, the internal voltage generation circuit for active state is provided to corresponding memory bank. Due to this, if many memory banks perform their operations in parallel, power consumed by the internal voltage generation circuits for active state rises. Although such high power consumption does not pose a serious problem in normal operation, this disadvantageously causes excess of current over a current standard in active-standby states.

### SUMMARY OF THE INVENTION

It is therefore an object of the present invention to provide an improved semiconductor memory device that can reduce power consumed by internal voltage generation circuits in active-standby states.

The above and other objects of the present invention can be accomplished by a semiconductor memory device comprising: n memory banks, where n is an integer more than 1; a first internal voltage generation circuit allocated to corresponding m memory banks, where m is an integer equal to or smaller than the n; and a second internal voltage generation circuit allocated to corresponding p memory banks, where p is an integer equal to or smaller than the n, wherein the first internal voltage generation circuit supplies an internal voltage when one of the corresponding banks is in an active state, and the second internal voltage generation circuit supplies the internal voltage in a period in which one of the corresponding banks is in the active state and in which a predetermined operation is performed.

In the present invention, it is preferable that the second internal voltage generation circuit is higher in power supply capability than the first internal voltage generation circuit. Preferably, the semiconductor memory device according to the present invention, further comprises a third internal voltage generation circuit supplying the internal voltage if at least the n memory banks are on standby. Preferably, the semiconductor memory device according to the present invention further comprises a fourth internal voltage generation circuit allocated to correspond to q memory bank, where q is an integer equal to or smaller than m, wherein the fourth internal voltage generation circuit supplies the internal voltage if one of the q corresponding memory banks is active.

According to the present invention, the semiconductor memory device includes two types of internal voltage generation circuits each supplying an internal voltage if one of the corresponding memory banks is active. Among them, the second internal voltage generation circuit is activated only while an operation accompanied by high power consumption such as a burst operation is performed. Due to this, even if many memory banks perform their operations in parallel, the power consumed by the internal voltage generation circuits themselves can be suppressed. It is, therefore, possible to lessen the probability of exceeding the current standard in the active/standby states.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic plan view showing a configuration of a semiconductor memory device according to a first embodiment of the present invention;

FIG. 2A shows a circuit generating a bank active signal ACTU;

FIG. 2B shows a circuit generating a bank active signal ACTD;

FIG. 3 is a circuit diagram of each of the first and second internal voltage generation circuits VPERIACTG, VPERIACTU1, and VPERIACTD1;

FIG. 4 is a circuit diagram of the third internal voltage generation circuit VPERISTY;

FIG. 5 is a circuit diagram of the comparator shown in FIG. 3;

FIG. 6 is a circuit diagram of the comparator shown in FIG. 4;

FIG. 7 is a timing chart for explaining operation performed by the semiconductor memory device according to the first embodiment of the present invention; and

FIG. 8 is a schematic plan view showing a configuration of the semiconductor memory device according to the second embodiment of the present invention.

### DETAILED DESCRIPTION OF THE EMBODIMENTS

Preferred embodiments of the present invention will now be described below in detail with reference to the accompanying drawings.

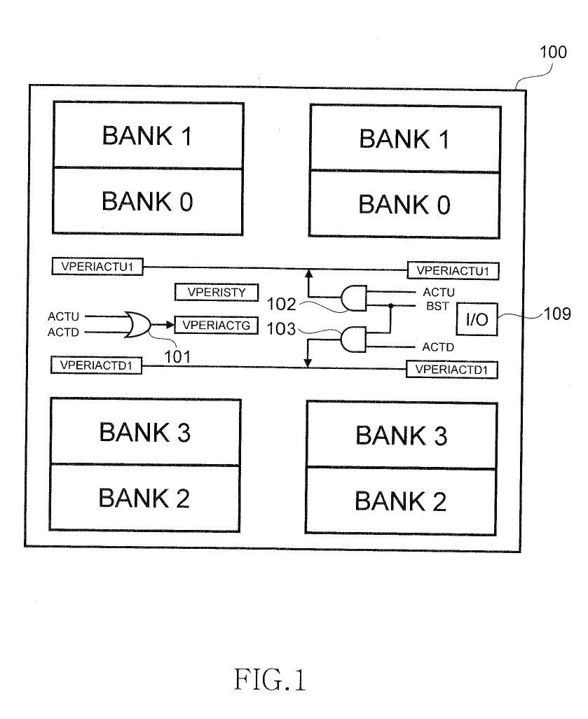

FIG. 1 is a schematic plan view showing a configuration of a semiconductor memory device according to a first embodiment of the present invention.

The semiconductor memory device according to the first embodiment is, for example, a DRAM. As shown in FIG. 1, a memory cell array on a chip 100 is divided into four memory banks BANK0 to BANK3. Commands can be individually issued from outside of the chip 100 to the respective memory banks BANK0 to BANK3. The memory banks BANK0 to BANK3 have different active periods accordingly.

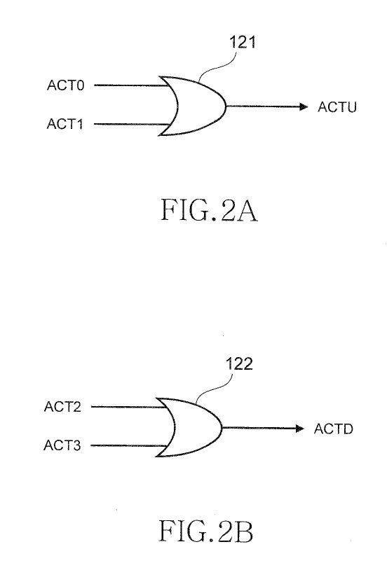

The memory banks BANK0 to BANK3 are activated in response to corresponding bank active signals ACT0 to ACT3, respectively. As shown in FIG. 2A, among the bank active signals ACT0 to ACT3, the bank active signals ACT0 and ACT1 are input to an OR circuit 121, thereby generating a bank active signal ACTU. Likewise, as shown in FIG. 2B, the bank active signals ACT2 and ACT3 are input to an OR circuit 122, thereby generating a bank active signal ACTD.

On the chip 100, regions among the memory banks are used as peripheral circuit regions in which peripheral circuits such as a controller and a decoder are arranged. The peripheral circuits also include a circuit transferring data between each of the memory banks BANK0 to BANK3 and an input/output circuit 109 and the like.

An internal voltage VPERI that is an operating voltage for the peripheral circuits is generated by three types of internal voltage generation circuits. Namely, a first internal voltage generation circuit VPERIACTG is allocated to the memory banks BANK0 to BANK3 in common. Second internal voltage generation circuits VPERIACTU1 and VPERIACTD1 are allocated to the memory banks BANK0 and BANK1 and to the memory banks BANK2 and BANK3, respectively. A third internal voltage generation circuit VPERISTY is allocated to the memory banks BANK0 to BANK3 in common.

The first internal voltage generation circuit VPERIACTG supplies the internal voltage VPERI in response to an output of an OR circuit 101 receiving the bank active signals ACTU and ACTD. Due to this, the first internal voltage generation circuit VPERIACTG supplies the internal voltage VPERI when one of the banks BANK0 to BANK3 is active. A power supply capability of the first internal voltage generation circuit VPERIACTG is designed so as to supply enough power consumed in a period in which the four BANK0 to BANK3 are all active but in which the input/output circuit 109 does not perform a burst operation.

The second internal voltage generation circuit VPERIACTU1 supplies the internal voltage VPERI in response to an output of an AND circuit 102 receiving the bank active signal ACTU and a burst signal BST. The second internal voltage generation circuit VPERIACTD1 supplies the internal voltage VPERI in response to an output of an AND circuit 103 receiving the bank active signal ACTD and the burst signal BST. The burst signal BST is a signal activated in a period in which the input/output circuit 109 performs the burst operation (a burst input operation or burst output operation).

Accordingly, the second internal voltage generation circuit VPERIACTU1 supplies the internal voltage VPERI in a period in which one of the banks BANK0 and BANK1 is active and in which the input/output circuit 109 performs the burst operation. Likewise, the second internal voltage generation circuit VPERIACTD1 supplies the internal voltage VPERI in a period in which one of the banks BANK2 and BANK3 is active and in which the input/output 109 circuit performs the burst operation. A power supply capability of each of the second internal voltage generation circuits VPERIACTU1 and VPERIACTD1 is designed so as to supply enough power consumed in the period of the burst operation in which the power consumption is the highest.

The third internal voltage generation circuit VPERISTY is a circuit constantly supplying the internal voltage VPERI. A power supply capability of the third internal voltage generation circuit VPERISTY is designed so as to stabilize the internal voltage VPERI in a period in which all the memory banks BANK0 to BANK3 are on the standby state. Accordingly, the power supply capability of the third internal voltage generation circuit VPERISTY is designed so as to supply enough power consumed in the period in which all the four memory banks BANK0 to BANK3 are on the standby state.

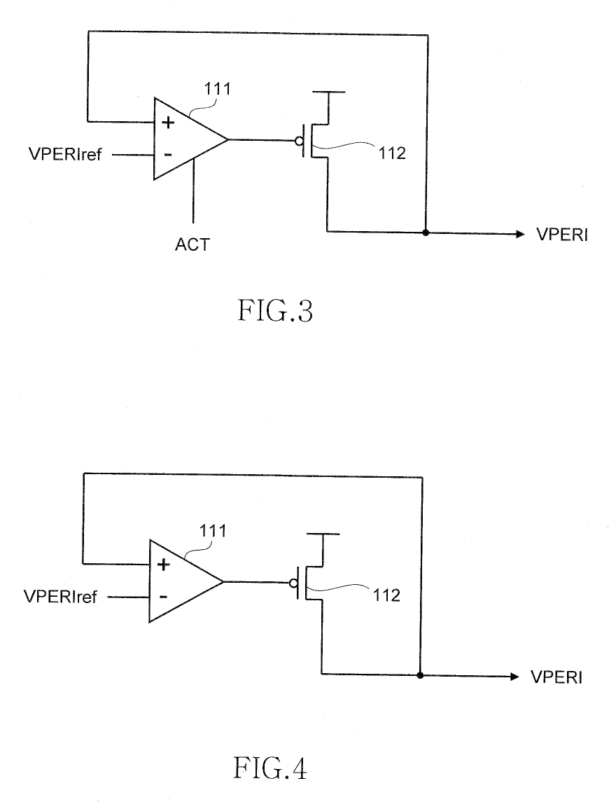

FIG. 3 is a circuit diagram of each of the first and second internal voltage generation circuits VPERIACTG, VPERIACTU1, and VPERIACTD1. FIG. 4 is a circuit diagram of the third internal voltage generation circuit VPERISTY.

As shown in FIGS. 3 and 4, these internal voltage generation circuits are almost identical in circuit configuration. Namely, each of the internal voltage generation circuits is configured to include a comparator 111 comparing a reference voltage VPERIref with the internal voltage VPERI and a P channel MOS transistor 112 controlled by an output of the comparator 111. However, the first and second internal voltage generation circuits VPERIACTG, VPERIACTU1, and VPERIACTD1, and the third internal voltage generation circuit VPERISTY differ in the following respect. The corresponding bank active signal ACT is supplied to the comparator 111 included in the first and second internal voltage generation circuits VPERIACTG, VPERIACTU1, and VPERIACTD1, and the comparator 111 performs a comparison operation only in a period where the bank active signal ACT is active. No such activation signal is supplied to the comparator 111 included in the third internal voltage generation circuit VPERISTY, so that the comparator 111 constantly performs a comparison operation.

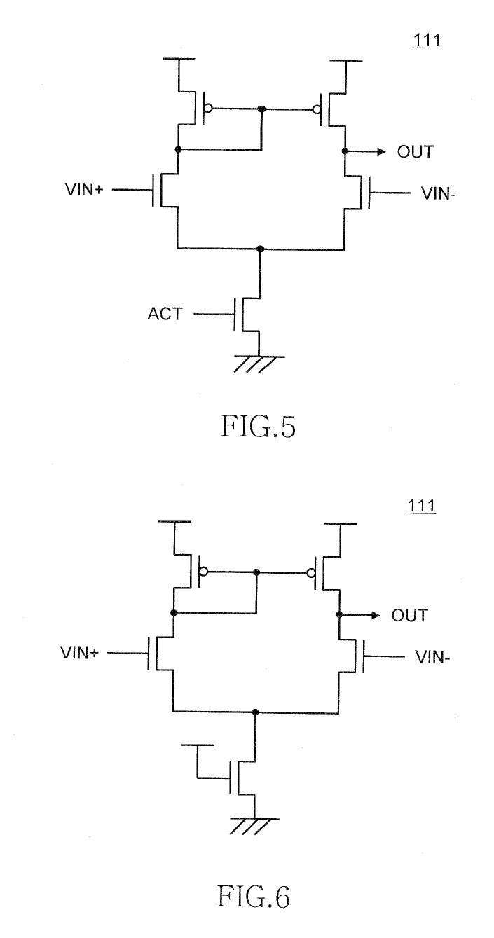

FIG. 5 is a circuit diagram of the comparator 111 shown in FIG. 3, and FIG. 6 is a circuit diagram of the comparator 111 shown in FIG. 4. As shown in FIGS. 5 and 6, each of the comparators 111 is configured to include a differential amplifier circuit. However, in the circuit diagram of FIG. 5, the bank active signal ACT is supplied to a gate of an N channel MOS transistor constituting a current source. In the circuit diagram of FIG. 6, a gate of an N channel MOS transistor constituting a current source is fixed to high level.

With the above configurations, each of the internal voltage generation circuits turns on the transistor 112 to raise the internal voltage VPERI when the internal voltage VPERI is reduced to be lower than the reference voltage VPERIref. The internal voltage VPERI can be thereby kept almost constant.

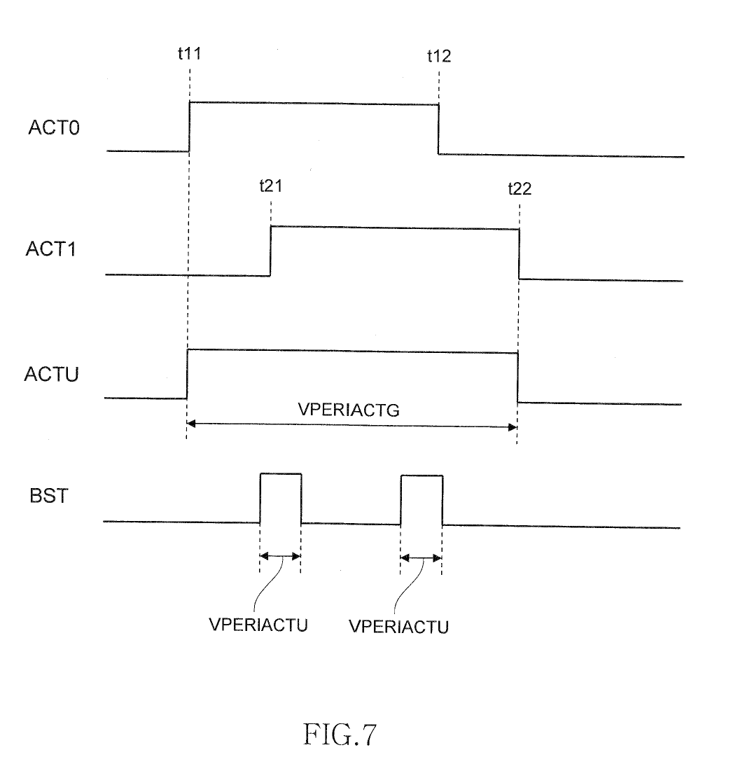

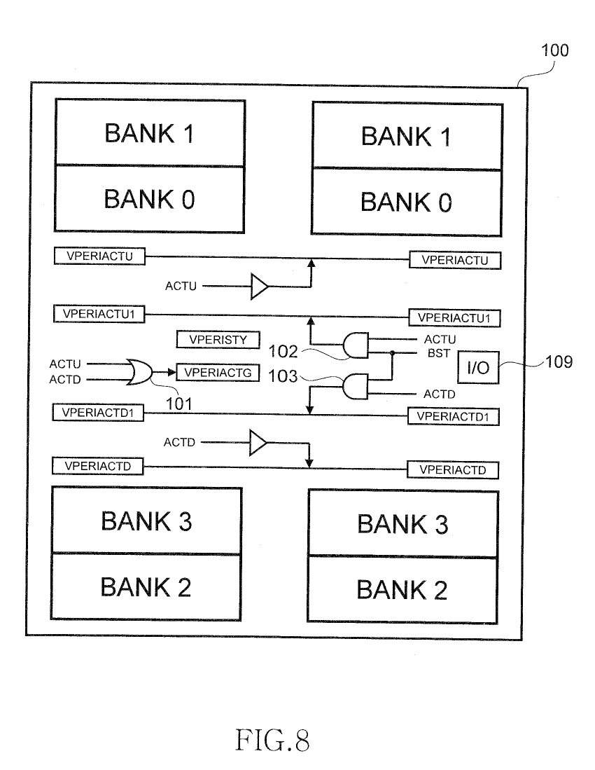

FIG. 7 is a timing chart for explaining operation performed by the semiconductor memory device according to the first embodiment.

In the example of FIG. 7, the bank active signal ACT0 is activated in a period from time t11 to time t12, and the bank active signal ACT1 is activated in a period from time t21 to time t22. In this case, the bank active signal ACTU is activated in a period in which at least one of the bank active signals ACT0 and ACT1 is activated, i.e., in a period from the time t11 to the time t22. Accordingly, in the period from the time t11 to the time t22, the first internal voltage generation circuit VPERIACTG is activated to supply the internal voltage VPERI with the relatively medium driving capability.

Furthermore, if the burst operation is performed while the bank active signal ACT0 is active, the burst signal BST is activated in the period in which the bank active signal ACT0 is active. Likewise, if the burst operation is performed while the bank active signal ACT1 is active, the burst signal BST is activated in the period in which the bank active signal ACT is active. Accordingly, the second internal voltage generation circuit VPERIACTU1 is activated to supply the internal voltage VPERI with the high driving in these respective periods.

As described above, the semiconductor memory device according to the first embodiment includes the two types of internal voltage generation circuits each supplying the internal voltage VPERI when at least one of the memory banks is active. Among these internal voltage generation circuits, the first internal voltage generation circuit VPERIACTG supplies power for the period in which the input/output 109 circuit does not perform the burst operation, and the second internal voltage generation circuits VPERIACTU1 and VPERIACTD1 supply the power for the period of the burst operation in which the power consumption is the highest. Due to this, even if many memory banks perform their operations in parallel, the overall power consumed by the internal voltage generation circuits is suppressed. It is, therefore, possible to lessen the probability of exceeding the current standard in the active-standby states.

A semiconductor memory device according to a second embodiment of the present invention will be described next.

FIG. 8 is a schematic plan view showing a configuration of the semiconductor memory device according to the second embodiment.

The semiconductor memory device according to the second embodiment differs from the first embodiment in that a fourth internal voltage generation circuits VPERIACTU and VPERIACTD allocated to the banks BANK0 and BANK1 and the banks BANK2 and BANK3, respectively are employed. Since other features of the second embodiment are identical to those of the first embodiment, like elements are denoted by like reference numerals and redundant explanations thereof will be omitted.

The fourth internal voltage generation circuits VPERIACTU and VPERIACTD supply the internal voltage VPERI in response to the bank active signals ACTU and ACTD, respectively. Due to this, the fourth internal voltage generation circuit VPERIACTU supplies the internal voltage VPERI if one of the banks BANK0 and BANK1 is active. The fourth internal voltage generation circuit VPERIACTD supplies the internal voltage VPERI if one of the banks BANK2 and BANK3 is active.

Preferably, power supply capabilities of these fourth internal voltage generation circuits VPERIACTU and VPERIACTD are deigned to be set between the power supply capability of the first internal voltage generation circuit VPERIACTG and that of the second internal voltage generation circuits VPERIACTU1 and VPERIACTD1.

According to the second embodiment, the semiconductor memory device additionally includes the fourth internal voltage generation circuits VPERIACTU and VPERIACTD each supplying the internal voltage VPERI if one of the corresponding memory banks is active. The semiconductor memory device according to the second embodiment is suited for a case where the power consumption is relatively high when at least one of the memory banks is active.

While a preferred embodiment of the present invention has been described hereinbefore, the present invention is not limited to the aforementioned embodiment and various modifications can be made without departing from the spirit of the present invention. It goes without saying that such modifications are included in the scope of the present invention.

For example, in the first and second embodiments, only one first internal voltage generation circuit VPERIACTG is provided to correspond to all the memory banks BANK0 to BANK3. However, the number of the first internal voltage generation circuits VPERIACTG is not particularly limited. Therefore, a plurality of first internal voltage generation circuits VPERIACTG can be provided to be allowed to selectively operate according to the memory banks that turn active.

Moreover, in the first and second embodiments, one second internal voltage generation circuit VPERIACTU1 or VPERIACTD1 is provided to correspond to the two memory banks BANK0 and BANK1 or BANK2 and BANK3. However, the number of the second internal voltage generation circuits VPERIACTU1 and VPERIACTD1 is not particularly limited. Therefore, a plurality of second internal voltage generation circuits VPERIACTU1 and VPERIACTD1 can be allocated to correspond to the respective memory banks BANK0 to BANK3.

Likewise, in the second embodiment, one fourth internal voltage generation circuit VPERIACTU or VPERIACTD is provided to correspond to the two memory banks BANK0 and BANK1 or BANK2 and BANK3. However, the number of the fourth internal voltage generation circuits VPERIACTU and VPERIACTD is not particularly limited. Therefore, a plurality of fourth internal voltage generation circuits VPERIACTU and VPERIACTD can be allocated to correspond to the respective memory banks BANK0 to BANK3.

Furthermore, in the first and second embodiments, the second internal voltage generation circuits VPERIACTU1 and VPERIACTD1 are activated in the period of the burst operation. The operation that gives a trigger to activating the second internal voltage generation circuits VPERIACTU1 and VPERIACTD1 is not limited to the burst operation but can be another operation in which the power consumption increases.

What is claimed is:

1. A semiconductor memory device comprising:
n memory banks, where n is an integer more than 1;
a first internal voltage generation circuit allocated to corresponding m memory banks, where m is an integer equal to or smaller than the n; and
a second internal voltage generation circuit allocated to corresponding p memory banks, where p is an integer equal to or smaller than the n, wherein
the first internal voltage generation circuit supplies an internal voltage when one of corresponding banks is in an active state, and
the second internal voltage generation circuit supplies the internal voltage in a period in which one of corresponding banks is in the active state and in which a predetermined operation is performed.

2. The semiconductor memory device as claimed in claim 1, wherein the second internal voltage generation circuit is higher in power supply capability than the first internal voltage generation circuit.

3. The semiconductor memory device as claimed in claim 1, wherein the p is more than 1 and smaller than the m.

4. The semiconductor memory device as claimed in claim 1, wherein the m is equal to the n.

5. The semiconductor memory device as claimed in claim 1, further comprising a third internal voltage generation circuit supplying the internal voltage if at least the n memory banks are in a standby state.

6. The semiconductor memory device as claimed in claim 1, further comprising a fourth internal voltage generation circuit allocated to correspond to q memory bank, where q is an integer equal to or smaller than m, wherein the fourth internal voltage generation circuit supplies the internal voltage if one of the q corresponding memory banks is in the active state.

7. The semiconductor memory device as claimed in claim 6, wherein the q is equal to the p.

8. The semiconductor memory device as claimed in claim 1, wherein the predetermined operation is a burst operation.
